(19) United States
(12) Patent Application Publication
(10) Pub. No.: US 2008/0302412 A1
(43) Pub. Date: Dec. 11, 2008

(54) PHOTOVOLTAIC POWER DEVICE AND MANUFACTURING METHOD THEREOF

(75) Inventors: Hsi-Chieh CHEN, Hsinchu (TW); Chih-Hsun CHU, Hsinchu (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: MOSEL VITELIC, INC., Hsinchu (TW)

(21) Appl. No.: 11/935,882

(22) Filed: Nov. 6, 2007

(30) Foreign Application Priority Data
Jun. 11, 2007 (TW) 096121069

(51) Int. Cl. H01L 31/04

(52) U.S. Cl. 136/252

(57) ABSTRACT

A photovoltaic power device is provided. The photovoltaic power device includes a donor substrate, a first emitting substrate; a second emitting substrate, a first anti-reflection layer, a first metal electrode, a second metal electrode and a second anti-reflection layer. In the photovoltaic power device, the first and the second emitting substrate are disposed in the opposite sides of the donor substrate to generate two electronic flows, and the first metal electrode is insulated from the second metal electrode by the second anti-reflection layer.

### FIELD OF THE INVENTION

The present invention relates to a photovoltaic power device and a manufacturing method, and more particular to a photovoltaic power device and a manufacturing method for increasing the power generating efficiency.

### BACKGROUND OF THE INVENTION

Since the industrial revolution, the requirement for the power is larger and larger that results in the problems including the growing pollutions and the running out of the fossil fuel. Nowadays, the need for the alternative power sources in the whole world is very urgent, so there are more and more large invention projects putting in huge money to investigate and develop the alternative power sources. However, among the numerous alternative power schemes, the solar cell almost becomes the main stream of the alternative power. Presently, the developed countries including the America, Germany, Japan and so on all develop the solar cell by the government power.

The concept of the solar cell refers to the Photovoltaic effect that uses the semiconductor element to convert the solar power into the electronic power. Basically, the structure of the solar cell is a PN junction diode with a big area, so that the manufacturing method of the solar cell is similar to the semiconductor but easier. The power of the solar cell comes from the sun light where the main spectrum is the visible light with the wavelength in the range from 0.3 micrometer ultraviolet to several micrometer infrared. The photon energy is around 0.3 to 4 electronic volts, so the material having the energy gap in this range, like silicon, will have better photo-electronic converting efficiency.

In the periodic table of elements, silicon has an atomic number of fourteen, the crystal thereof is diamond structure and it belongs to the IV group elements. The so-called IV elements mean that there are four electrons in the outer layer orbit area surrounding the atom core which are called valence electrons. Each of the four valence electrons of each silicon atom is respectively combined with one of four valence electrons near the silicon atom to form an electronic pair called covalent bond. If an atom with five valence electrons (V atom), like phosphorous, is intermingled into the pure silicon, the intermingled V atom will replace the central position of the silicon atom. However, when the phosphorous atom with five valence electrons form the covalent bonds with the nearby silicon atom, there will be one more electron left, called the free electron, which is a carrier carrying negative charge. The intermingling atom, like phosphorous, which provides the free electrons is usually called a donor, and the semiconductor intermingled with the donor is called an N-type semiconductor. Similarly, if a III atom, such as boron, is intermingled into the pure silicon, the intermingled III atom will also replace the central position of the silicon atom. However, the boron atom only provides three valence electrons to form the covalent bonds with the nearby silicon atom, which generates an opening called an electron hole that serves as a carrier carrying positive charge. The intermingled atom, like boron, which provides the electron hole is usually called a receiver, and the semiconductor intermingled with the receiver is called a P-type semiconductor.

The ordinary solar cell manufacturing method uses the P-type semiconductor intermingled with few boron atoms as a substrate. Then, the phosphorous atoms, which have a little bit higher concentration than the boron atoms, is intermingled into the P-type semiconductor to form a P-N junction by using a high temperature thermal diffusion method. The P-N junction is composed of the donor with the ion and the receiver with the cation. There is a built-in potential in the area with both the ion and cation which can drive the movable carriers therein, so the area is called a depletion region. When the P-N semiconductor is illuminated, the energy provided by the photon stimulates the electron in the semiconductor to generate the electron-electronic hole pair. The electron and the electronic hole are both affected by the built-in potential, wherein the electronic hole moves toward the direction of the electric field and the electron moves toward the direction opposite thereto. If the two electrodes are connected with a load to form a loop, there will be a current flowing through the load. The above descriptions are the principle of the solar cell operation.

Please refer to FIGS. 1A-1G, which show the manufacturing process of the conventional solar cell. Firstly, the P-type semiconductor 10 is provided to serve as a substrate, as shown in FIG. 1A. Secondly, two layers of N-type semiconductors 11, 12 are formed on the upper and bottom surfaces of the P-type semiconductor through thermal diffusion, as shown in FIG. 1B. Thirdly, the SiN anti-reflection layer 13 is formed on the upper layer N-type semiconductor 11, as shown in FIG. 1C. Fourthly, the silver metal bus lines 14 (there number thereof is usually two) is formed on the bottom layer N-type semiconductor 12, as shown in FIG. 1D. Fifthly, the remaining area of the bottom layer N-type semiconductor 12 is covered by the Aluminum metal layer 15, as shown in FIG. 1E. Sixthly, plural silver metal conductors 16 are formed on the anti-reflection layer 13, as shown in FIG. 1F. Seventhly, the whole construction is heated to make each metal element permeate into the semiconductor to become the alloy, wherein the plural silver metal conductors 16 are fused with the upper layer N-type semiconductor layers to become N emitter contacts 16′, i.e. the negative electrode. The aluminum metal layer 15 is fused with the bottom layer N-type semiconductor 12 to become the P⁺-type semiconductor 15′. The silver metal bus lines 14 are fused with the aluminum metal layer 15 to become the silver/aluminum alloy P⁺ contact 14′, i.e. the positive electrode.

In the conventional solar cell described above, there is only one P-N junction to serve as the electron diffusion channel. Actually, the ratio of the thickness of the P-type semiconductor to that of the N-type semiconductor in the conventional solar cell is very large, i.e. the thickness of the P-type semiconductor is around 200 μm and that of the N-type semiconductor is around 0.3 μm. Therefore, the conventional solar cell cannot efficiently use the potential power in the P-type semiconductor.

In order to overcome the drawbacks in the prior art, a photovoltaic power device and the manufacturing method thereof are provided. The particular design in the present invention not only solves the problems described above, but also is easy to be implemented. Thus, the invention has the utility for the industry.

### SUMMARY OF THE INVENTION

In accordance with an aspect of the present invention, a photovoltaic power device is provided. The photovoltaic power device includes a donor substrate receiving a light and generating a first voltage; a first emitting substrate connected to a first surface of the donor substrate for receiving a first electronic flow; a second emitting substrate connected to a second surface of the donor substrate for receiving a second electronic flow; a first anti-reflection layer covering the first emitting substrate for avoiding a light reflection; a first metal electrode disposed on the first anti-reflection layer and merged with the first emitting substrate for transmitting the first electronic flow; a second metal electrode disposed on the second emitting substrate and merged with the second emitting substrate for generating a second voltage; a second anti-reflection layer covering the second metal electrode; and a third metal electrode disposed on the second anti-reflection layer and merged into the second emitting substrate for transmitting the second electronic flow, wherein the second voltage is larger than the first voltage, and the first metal electrode is insulated from the second metal electrode by the second anti-reflection layer.

According to the photovoltaic power device described above, the donor substrate is a P-type substrate and the first and the second emitting substrates are N-type substrates.

According to the photovoltaic power device described above, the first and the second anti-reflection layers are made of silicon nitride.

According to the photovoltaic power device described above, the first and the third metal layers are made of silver.

According to the photovoltaic power device described above, the second metal layer is made of aluminum.

In accordance with another aspect of the present invention, a photovoltaic power device is provided. The photovoltaic power device includes a first substrate with a first surface and a second surface opposite to the first surface for generating a first voltage by receiving a light; a second substrate connected to the first surface for receiving a first electronic flow; and a third substrate connected to the second surface for receiving a second electronic flow.

Preferably, the photovoltaic power device described above further includes a first anti-reflection layer covering the second substrate for avoiding a light reflection and a first metal electrode disposed on the first anti-reflection layer and merged with the second substrate for transmitting the first electronic flow.

Preferably, the photovoltaic power device described above further includes a second metal electrode disposed on the third substrate and merged into the third substrate for generating a second voltage; a second anti-reflection layer covering the second metal electrode; and a third metal electrode disposed on the second anti-reflection layer and merged into the third substrate for transmitting the second electronic flow, wherein the second voltage is larger than the first voltage, and the first metal electrode is insulated from the second metal electrode by the second anti-reflection layer.

According to the photovoltaic power device described above, the first and the second anti-reflection layers are made of silicon nitride.

According to the photovoltaic power device described above, the first and the third metal layers are made of silver.

According to the photovoltaic power device described above, the second metal layer is made of aluminum.

According to the photovoltaic power device described above, the first substrate is a P-type substrate, and the second and the third emitting substrates are N-type substrates.

In accordance with a further aspect of the present invention, a method for manufacturing a photovoltaic power device is provided. The method includes steps of providing a donor substrate; configuring a first and a second emitting substrates respectively connected to a first surface and a second surface of the donor substrate; configuring a first anti-reflection layer covering the first emitting substrate; configuring a first metal electrode on the first anti-reflection layer; configuring a second metal electrode on the second emitting substrate; configuring a second anti-reflection layer covering the second metal electrode; configuring a third metal electrode on the second anti-reflection layer; and heating the above components for merging the first metal electrode with the first emitting substrate, and merging the second and the third metal electrodes with the second emitting substrate.

According to the method described above, the donor substrate is a P-type substrate and the first and the second emitting substrates are N-type substrates.

According to the method described above, the first and the second anti-reflection layers are made of silicon nitride.

According to the method described above, the first and the third metal layers are made of silver.

According to the method described above, the second metal layer is made of aluminum.

The above contents and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1A-1G show the manufacturing process and the structure of the conventional solar cell;

FIGS. 2A-2E show the manufacturing process and the structure of the photovoltaic power device according to a preferred embodiment of the present invention;

FIG. 3 shows the disposition of the aluminum conductor 24 in the bottom layer of the photovoltaic power device according to a preferred embodiment of the present invention; and

FIG. 4 shows the disposition of the silver conductor 26 in the bottom layer of the photovoltaic power device according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purposes of illustration and description only; it is not intended to be exhaustive or to be limited to the precise form disclosed.

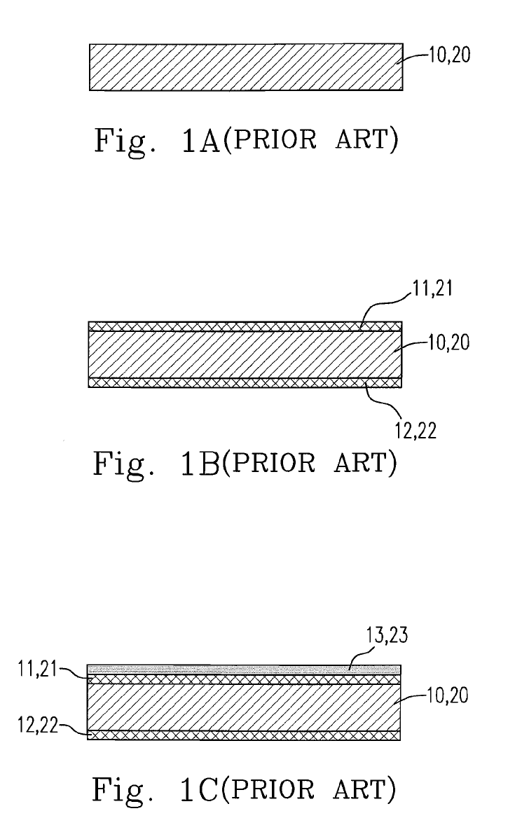

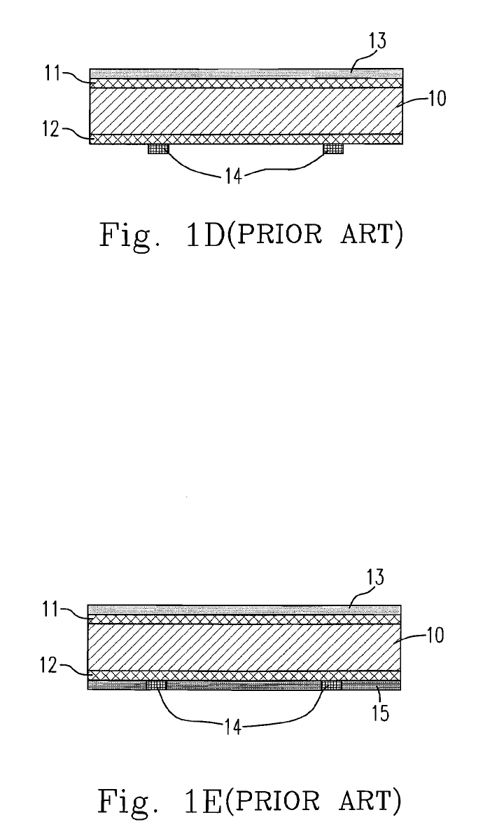

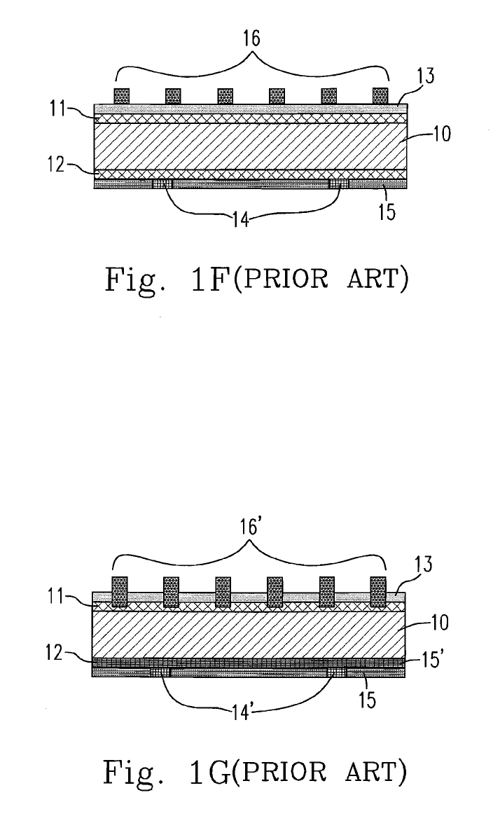

The initial manufacturing process of the photovoltaic power device of the present invention is the same as the conventional solar cell, as shown in FIGS. 1A-1C, which includes providing the P-type semiconductor to serve as a substrate 20, forming two layers of N-type semiconductors on the upper and bottom surfaces of the substrate 20 through thermal diffusion to form the upper and bottom emitting layers 21,22, and forming a silicon nitride layer on the surface of the upper emitting layer 21 to form the first anti-reflection layer 23.

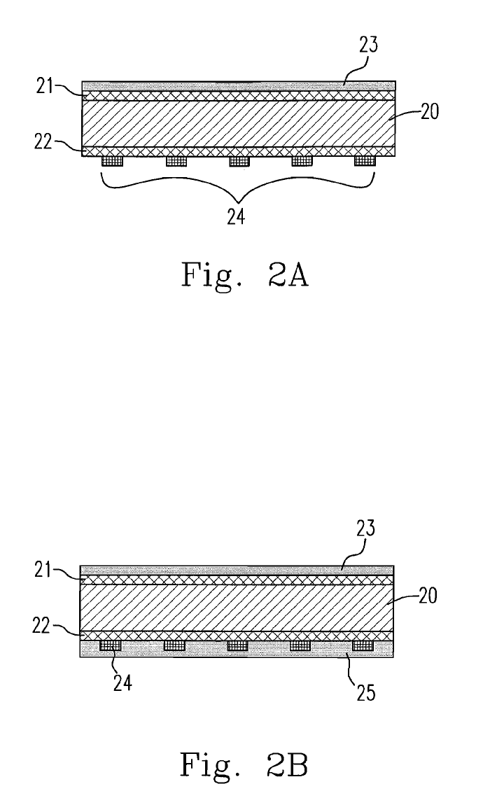

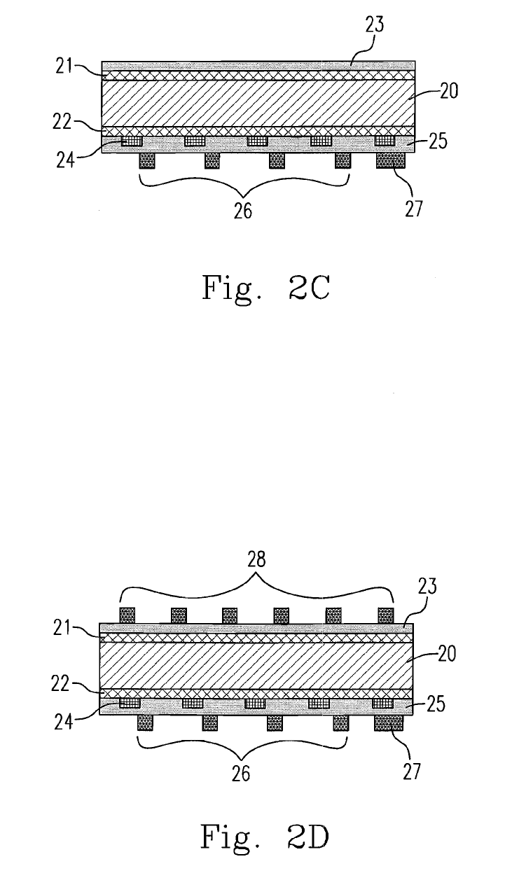

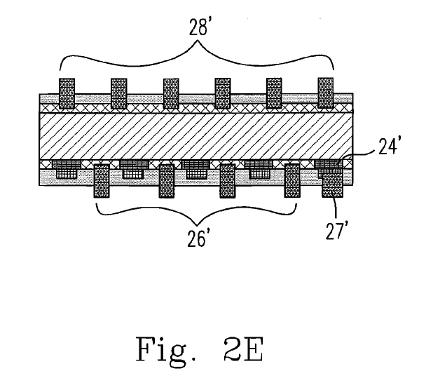

The second step is to form plural aluminum metal conductors 24 on the surface of the bottom emitting layer 22, as shown in FIG. 2A. The third step is to form a silicon nitride layer over the surface of the bottom emitting layer 22 and the aluminum metal conductors 24 to form the second anti-reflection layer 25, as shown in FIG. 2B. The fourth step is to form plural first silver metal conductors 26 and an independent silver bus conductor 27 on the surface of the second anti-reflection layer 25, as shown in FIG. 2C. The fifth step is to form plural second silver conductors 28 on the surface of the first anti-reflection layer 23, as shown in FIG. 2D. The sixth step is to heat the whole device to make the metal elements permeate into the semiconductor and alloy therewith. The plural second silver metal conductors 28 are alloyed with the upper emitting layer 21 to form N first emitter contacts 28′, i.e. the first negative electrode. The plural first silver metal conductors 26 are alloyed with the bottom emitting layer 22 to form N second emitter contacts 26′, i.e. the second negative electrode. The plural aluminum metal conductors 24 are also alloyed with the bottom emitting layer 22 to form the P⁺-type semiconductor 24′, and the independent silver bus conductor 27 is alloyed with the aluminum conductors 24 to form the sliver/aluminum alloy P⁺ contact 27′, i.e. the positive electrode.

According to the structure described above, the photovoltaic power device of the present invention increases a set of silver metal conductors 26 on the bottom layer of the conventional P-N substrate to form the N second emitter contacts 26′, which makes the P-N electronic flow caused by the light have an additional emitting layer. Therefore, the electron emitting area of the photovoltaic power device is increased and the electron in the deep of the P-type semiconductor is used sufficiently. Accordingly, the power generating efficiency of the present invention is much better than that of the conventional solar cell.

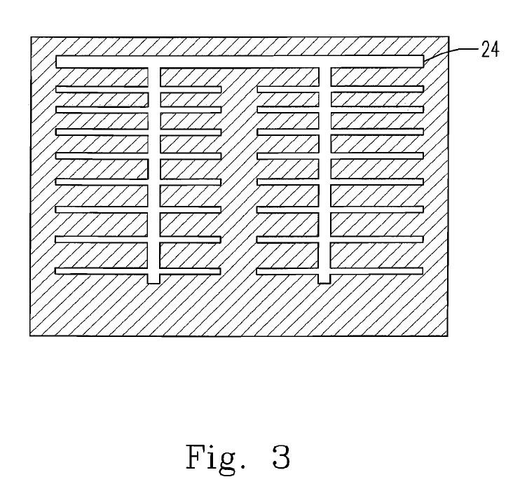

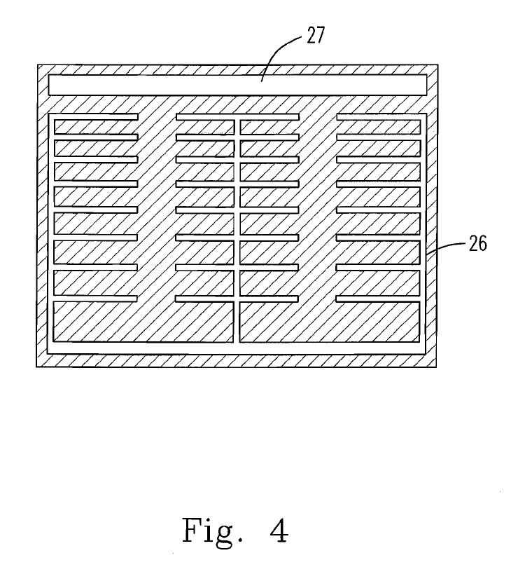

Please refer to FIGS. 3 and 4, which refer to one of the preferred embodiments. In this embodiment, since the present invention disposes the positive and the negative electrodes at the same side of the photovoltaic power device, the first sliver metal conductors 26 and the aluminum metal conductors 24 should be disposed interlacedly and extremely carefully to avoid the short circuit and obtain bigger areas respectively. Moreover, the present invention disposes a silicon nitride layer to serve as the second anti-reflection layer 25 between the first sliver metal conductors 26 and the aluminum metal conductors 24 to isolate them in different layers for avoiding the short circuit due to contact therebetween. There is an independent silver metal bus conductor 27 in the first silver metal conductors 26 which is used to overlay the aluminum metal conductors 24 to form the silver/aluminum alloy after heating. The silver/aluminum alloy serves as the P⁺ contact 27′, i.e. the positive electrode.

Moreover, the photovoltaic power device of the present invention is more convenient to be connected than the conventional solar cell during series connection. The conventional solar cell has only one negative electrode at the light-receiving side and one positive electrode at the opposite side. When the solar cells are serially connected, it is inconvenient to connect them from the upper layer to the bottom layer by the conductors. Since the photovoltaic power device of the present invention has two negative electrodes at both two sides thereof, when they are manufactured, they have to be connected first. Accordingly, the negative electrode can be disposed at either side of the photovoltaic power device, even in the middle of the conductor. During series connection, only a straight line conductor is needed to connect the positive electrode of one photovoltaic power device with the negative electrode of another photovoltaic power device. In accordance with the above descriptions, the present invention not only utilizes the potential of the P-N semiconductor more efficiently but also simplifies the series connection process.

While the invention has been described in terms of what is presently considered to be the most practical and preferred embodiment, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A photovoltaic power device, comprising:
a donor substrate receiving a light and generating a first voltage;
a first emitting substrate connected to a first surface of the donor substrate for receiving a first electronic flow;
a second emitting substrate connected to a second surface of the donor substrate for receiving a second electronic flow;
a first anti-reflection layer covering the first emitting substrate for avoiding a light reflection;
a first metal electrode disposed on the first anti-reflection layer and merged with the first emitting substrate for transmitting the first electronic flow;
a second metal electrode disposed on the second emitting substrate and merged with the second emitting substrate for generating a second voltage;
a second anti-reflection layer covering the second metal electrode; and
a third metal electrode disposed on the second anti-reflection layer and merged into the second emitting substrate for transmitting the second electronic flow,
wherein the second voltage is larger than the first voltage, and the first metal electrode is insulated from the second metal electrode by the second anti-reflection layer.

2. A photovoltaic power device as claimed in claim 1, wherein the donor substrate is a P-type substrate and the first and the second emitting substrates are N-type substrates.

3. A photovoltaic power device as claimed in claim 1, wherein the first and the second anti-reflection layers are made of silicon nitride.

4. A photovoltaic power device as claimed in claim 1, wherein the first and the third metal layers are made of silver.

5. A photovoltaic power device as claimed in claim 1, wherein the second metal layer is made of aluminum.

6. A photovoltaic power device, comprising:
a first substrate with a first surface and a second surface opposite to the first surface for generating a first voltage by receiving a light;
a second substrate connected to the first surface for receiving a first electronic flow; and
a third substrate connected to the second surface for receiving a second electronic flow.

7. A photovoltaic power device as claimed in claim 6 further comprising:
a first anti-reflection layer covering the second substrate for avoiding a light reflection; and
a first metal electrode disposed on the first anti-reflection layer and merged with the second substrate for transmitting the first electronic flow.

8. A photovoltaic power device as claimed in claim 7 further comprising:
a second metal electrode disposed on the third substrate and merged into the third substrate for generating a second voltage;
a second anti-reflection layer covering the second metal electrode; and
a third metal electrode disposed on the second anti-reflection layer and merged into the third substrate for transmitting the second electronic flow,
wherein the second voltage is larger than the first voltage, and the first metal electrode is insulated from the second metal electrode by the second anti-reflection layer.

9. A photovoltaic power device as claimed in claim 8, wherein the first and the second anti-reflection layers are made of silicon nitride.

10. A photovoltaic power device as claimed in claim 8, wherein the first and the third metal layers are made of silver.

11. A photovoltaic power device as claimed in claim 8, wherein the second metal layer is made of aluminum.

12. A photovoltaic power device as claimed in claim 6, wherein the first substrate is a P-type substrate, and the second and the third emitting substrates are N-type substrates.

13. A method for manufacturing a photovoltaic power device, comprising steps of:
providing a donor substrate;
configuring a first and a second emitting substrates respectively connected to a first surface and a second surface of the donor substrate;
configuring a first anti-reflection layer covering the first emitting substrate;
configuring a first metal electrode on the first anti-reflection layer;
configuring a second metal electrode on the second emitting substrate;
configuring a second anti-reflection layer covering the second metal electrode;
configuring a third metal electrode on the second anti-reflection layer; and
heating the above components for merging the first metal electrode with the first emitting substrate, and merging the second and the third metal electrodes with the second emitting substrate.

14. A method as claimed in claim 13, wherein the donor substrate is a P-type substrate and the first and the second emitting substrates are N-type substrates.

15. A method as claimed in claim 13, wherein the first and the second anti-reflection layers are made of silicon nitride.

16. A method as claimed in claim 13, wherein the first and the third metal layers are made of silver.

17. A method as claimed in claim 13, wherein the second metal layer is made of aluminum.
